(19) United States
(12) Patent Application Publication
(10) Pub. No.: US 2025/0011163 A1
(43) Pub. Date: Jan. 9, 2025

(54) ROTATION RATE SENSOR WITH A MICROMECHANICAL STRUCTURE, AND METHOD FOR OPERATING A ROTATION RATE SENSOR

(71) Applicant: Robert Bosch GmbH, Stuttgart (DE)

(72) Inventors: Kaushik Krishna Rangharajan, Pforzheim (DE); Manuel Dietrich, Reutlingen (DE)

(21) Appl. No.: 18/751,895

(22) Filed: Jun. 24, 2024

(30) Foreign Application Priority Data
Jul. 6, 2023 (DE) 10 2023 206 396.4

(51) Int. Cl. B81B 7/00; G01C 19/5776; G01P 15/08

(52) U.S. Cl. CPC B81B 7/0058; G01C 19/5776; G01P 15/08; B81B 2201/0242; B81B 2203/04

(57) ABSTRACT

A rotation rate sensor with a micromechanical structure and with a mass oscillator. The mass oscillator is drivable to a drive oscillation using a drive device. The rotation rate sensor is configured to protect the micromechanical structure and, during a time interval of a detected free fall situation, in such a way that a reduction of the amplitude of the drive oscillation is achieved. The free fall situation is signaled using a free fall signal supplied to the rotation rate sensor. The rotation rate sensor is configured in such a way that, after the reception of a further free fall signal signaling the end of the free fall situation, the drive device again drives the mass oscillator to its operative drive oscillation. The reduction of the amplitude of the drive oscillation is realized faster than in a mere dying-away process of the drive oscillation of the mass oscillator.

### CROSS REFERENCE

The present application claims the benefit under 35 U.S.C. § 119 of German Patent Application No. DE 10 2023 206 396.4 filed on Jul. 6, 2023, which is expressly incorporated herein by reference in its entirety.

### FIELD

The present invention relates to a rotation rate sensor with a micromechanical structure and with a mass oscillator.

### BACKGROUND INFORMATION

Micromechanical rotation rate sensors (also referred to below as IMU (inertial measurement unit)) are described in a variety of embodiments in the related art. A common functional principle is the detection of a rotation rate via the action of the Coriolis force associated therewith. For this purpose, one or more mass oscillators are set in periodic movement by an electrical drive movement so that the rotation produces a force acting perpendicularly to both the movement direction and the rotation vector. The periodic movement is maintained by a drive structure; the mass oscillator is coupled to the substrate of the micromechanical sensor by spring elements.

Such rotation rate sensors with continuous drive excitation tend to sometimes generate particles in the MEMS core in repeated fall tests. These particles produce an electrical short circuit, which leads to quite often larger static/dynamic offset displacements in one or more axes of the gyroscope, sometimes accompanied by increased noise.

The present invention therefore aims at solving the problem of particle generation in the MEMS core of a rotation rate sensor when (a) the mass oscillator is deflected from its rest position by the rotation rate sensor drive or performs an oscillatory movement, and (b) when the IMU (either autonomously or as part of an electronic device) is subjected to a collision with a surface that is caused by free fall (in gravity) from more than approximately 10 cm.

Methods for detecting a free fall on the basis of the magnitude of the signal of an acceleration sensor are generally described in the related art. The magnitude of the measured acceleration (in g) is defined as follows:

$${Acc}_{mag} = \sqrt{{Acc}_{x}^{2} + {Acc}_{y}^{2} + {Acc}_{z}^{2}}$$

Here, Accₓ², Acc_{y}² and Acc_{z}² are the accelerations (in g) in the respective direction of the axis.

Conventionally, a threshold value is used, below which the sensor is regarded to be free falling; this threshold value is defined as Accₜₕᵣₑₛₕ. This value is close to ˜0 g and typically depends on the temperature as well as generally further specifications, for example a defined acceleration offset (after the production process or soldering process), which are generally product-specific.

A typical output data rate (ODR) provided by conventional rotation rate sensors is approximately 200 Hz, resulting in a corresponding detection interval of 5 ms, i.e., new data are generated every 5 ms. The length of this time interval can cause delays in the detection of the free fall. If the drive movement or drive actuation is turned off when a free fall signal is detected, the process of the excited movement of the mass oscillator dying away naturally may take longer than the free fall so that the problem of particle generation in the MEMS core during impact continues to exist.

### SUMMARY

It is an object of the present invention to provide a rotation rate sensor that can actively achieve a reduction of the amplitude of the drive oscillation, in that the free fall situation is signaled by means of a free fall signal supplied to the rotation rate sensor, and the reduction of the amplitude of the drive oscillation of the mass oscillator is realized faster than in a mere dying-away process of the drive oscillation of the mass oscillator. This can advantageously ensure a higher level of safety for the sensors in a free fall situation.

The rotation rate sensor according to the present invention according to an example embodiment may have the advantage over conventional sensors that the oscillatory movement (or its amplitude) of the mass oscillator, in particular the drive oscillation thereof, can be reduced particularly effectively and, first and foremost, relatively quickly after reception (by the rotation rate sensor) of a signal indicating a free fall situation, so that the particle generation during impact can in particular be minimized. Due to fact that the free fall situation can necessarily only be detected with some delay (after its actual occurrence), it is assumed in the context of the present invention that there is a minimum duration of the free fall or the free fall situation (approximately a value that can be parameterized on the basis of ad-hoc use cases, for example some 10 ms to about 80 ms to 100 ms, corresponding to a height of fall of a few centimeters in the presence of a fall acceleration of approximately 1 g, i.e., near the earth's surface), so that an interrupt signal can be output to the rotation rate sensor in view of a possible impending collision/impact. According to the present invention, after reception of the free fall signal, the previous excitation of the harmonic oscillation of the mass oscillator of the rotation rate sensor by means of the drive electrodes is actively reduced (or its amplitude is reduced or the excitation is interrupted) in such a way that the particle generation during the subsequently possible impact is minimized as much as possible. According to the present invention, it is thus advantageously possible to protect the rotation rate sensor from destruction in free fall situations, or in particular at (or after) the end thereof. As soon as the IMU is no longer in free fall (or the free fall situation is no longer detected), the drive of the rotation rate sensor is reset to the standard operating conditions. According to the present invention, the possibility of actively interrupting or of reducing the amplitude of the oscillation is preferably realized in particular directly as part of the control loop for maintaining the setpoint value of the drive oscillation, whereby it is in particular made possible to influence the excitation of the oscillation of the mass oscillator quickly and actively.

According to an example embodiment of the present invention, a rotation rate sensor with a micromechanical structure and with a mass oscillator is provided, wherein the mass oscillator is drivable to a drive oscillation by means of a drive device, wherein the rotation rate sensor is configured to protect the micromechanical structure and, during a time interval of a detected free fall situation, in such a way that a reduction of the amplitude of the drive oscillation is achieved, wherein the free fall situation is signaled or detected by means of a free fall signal supplied to the rotation rate sensor, wherein the rotation rate sensor is furthermore configured in such a way that, after the reception of a further free fall signal signaling the end of the free fall situation, the drive device again drives the mass oscillator to its operative drive oscillation, wherein the reduction of the amplitude of the drive oscillation is realized faster than in a mere dying-away process of the drive oscillation of the mass oscillator.

Advantageous embodiments and developments of the present invention are disclosed herein.

According to a preferred example embodiment of the present invention, the rotation rate sensor is configured in such a way that, for bringing about the drive oscillation of the mass oscillator, the drive device is controlled by means of a drive controller comprising an amplifier device, and that the drive controller generates a drive control signal for bringing about the driving of the mass oscillator, and that, during a first portion of the time interval of the detected free fall situation, the amplifier device is operated in an operating mode with a minimum possible amplification factor, wherein the amplifier device is in particular designed as an operational amplifier. By actively intervening in the excitation of the oscillation of the mass oscillator (in particular by changing (reducing) the setpoint value) in this way, the drive oscillation (or its amplitude) can be reduced faster than naturally dying away or decaying would last.

According to a further preferred example embodiment of the present invention, the rotation rate sensor is configured in such a way that, for bringing about the drive oscillation of the mass oscillator, the drive device is controlled by means of the drive controller comprising a phase inversion device, that the drive controller generates a drive control signal for bringing about the driving of the mass oscillator, and that, during the first portion of the time interval of the detected free fall situation, the phase inversion device generates the drive control signal as a phase-inverted drive control signal. By means of such an inversion, the drive oscillation or its amplitude can be reduced particularly quickly.

According to a further preferred example embodiment of the present invention, the rotation rate sensor is configured in such a way that, in a second portion of the time interval of the detected free fall situation, the drive device and/or the drive control signal is switched off, wherein the second portion of the time interval of the detected free fall situation in particular begins after the first portion has ended, in particular immediately following the first portion, or begins, temporally spaced apart from the first portion, after a specified wait time. This effectively prevents the risk that the active intervention in the drive oscillation through a minimum possible amplification factor or also, in particular, through inversion results in a re-increasing oscillation after some time or causes a dying-away effect of the system to occur.

According to a further preferred example embodiment of the present invention, the rotation rate sensor is configured in such a way that the free fall situation is detected when a measured acceleration acting on the rotation rate sensor is detected as being less than an acceleration threshold value.

According to a further preferred example embodiment of the present invention, the rotation rate sensor comprises an acceleration sensor or is connected to an acceleration sensor, wherein the acceleration sensor is configured in such a way that the free fall situation is detected and the free fall signal is generated when the measured acceleration acting on the rotation rate sensor is detected as being less than the acceleration threshold value.

According to the present invention, this can be realized according to multiple variants; for example, it is possible that the free fall signal, which is generated by the acceleration sensor (accel), is provided to the rotation rate sensor within an inertial sensor structure (in particular in the form of a so-called combo ASIC comprising both the acceleration sensor (accel) and the rotation rate sensor (gyro)); in this case, it may in particular be advantageously provided that the signal processing of accel and gyro takes place via the same data path. The transmission of the free fall signal therefore does not necessarily have to be a traditional sensor-to-sensor communication. Alternatively, or cumulatively, according to one design variant, it is also furthermore provided according to the present invention that a corresponding signal (free fall signal) is triggered by a microcontroller or motion processor, internally or externally to the device, i.e., within or outside of the inertial sensor structure.

According to an example embodiment of the present invention, in a method for operating a rotation rate sensor with a micromechanical structure and with a mass oscillator, the mass oscillator is drivable to a drive oscillation by means of a drive device, wherein the rotation rate sensor is configured to protect the micromechanical structure and, during a time interval of a detected free fall situation, in such a way that a reduction of the amplitude of the drive oscillation is achieved, wherein the free fall situation is signaled by means of a free fall signal supplied to the rotation rate sensor, wherein the rotation rate sensor is furthermore configured in such a way that, after the reception of a further free fall signal signaling the end of the free fall situation, the drive device again drives the mass oscillator to its operative drive oscillation, wherein the reduction of the amplitude of the drive oscillation is realized faster than in a mere dying-away process of the drive oscillation of the mass oscillator.

### BRIEF DESCRIPTION OF THE DRAWINGS

FIG. 1 shows a schematic illustration of a control loop of the actuation electrodes or detection electrodes (feedback loop of the drive control loop or of the drive controller) for a rotation rate sensor with an amplifier device and with an indicated phase inversion device integrated in the control loop.

FIG. 2 shows a schematic illustration of a time curve of the drive amplitude with active interruption or reduction of the amplitude of the drive oscillation.

### DETAILED DESCRIPTION OF EXAMPLE EMBODIMENTS

In the various figures, identical parts are always provided with the same reference signs and are therefore generally also named or mentioned only once.

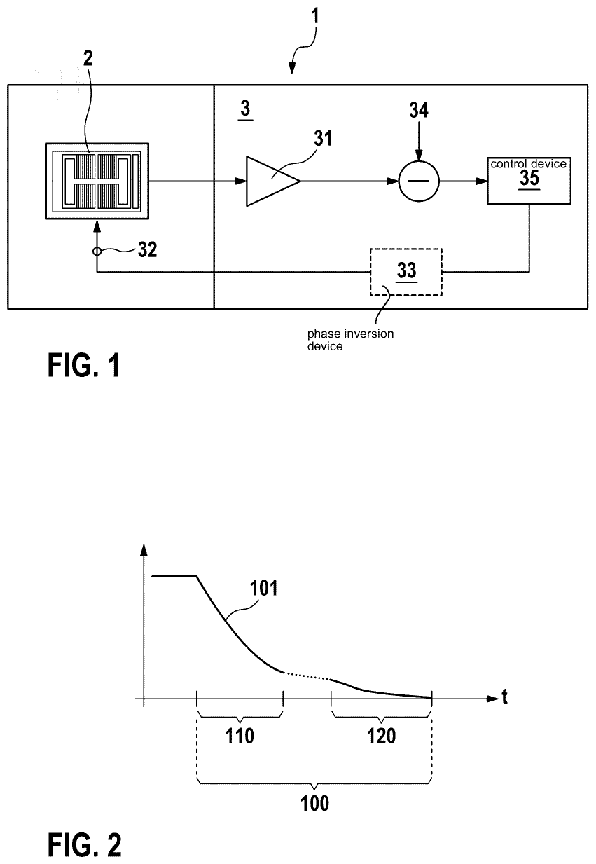

FIG. 1 schematically shows, for a rotation rate sensor 1, a control loop 3 of the drive electrodes or actuation electrodes and detection electrodes (feedback loop of the drive control loop 3 or drive controller 3) for a micromechanical structure 2 of the rotation rate sensor 1.

For the sake of simplicity, the drive electrodes are not specifically denoted by reference signs but are to be considered as part of the micromechanical structure 2. According to the exemplary representation in FIG. 1, the drive control loop or the drive controller 3 comprises an amplifier device 31. The amplifier device 31 according to the present invention is in particular an operational amplifier.

Furthermore, the drive control loop or the drive controller 3 returns to the micromechanical structure 2 a drive control signal 32 for bringing about the driving of the mass oscillator (for the sake of simplicity, the mass oscillator is also not specifically shown in FIG. 1 and not provided with a reference sign). Furthermore, the drive control loop or the drive controller 3 comprises, in a conventional manner, an input 34 for a reference signal as well as a control device 35.

According to a first design variant or embodiment of the present invention, it is provided that, for faster or more effective reduction of the (amplitude of the) drive oscillation of the mass oscillator (excited by the drive controller 3), the amplifier device 31 is adjusted or operated, that the amplifier device 31 is operated (in an operating mode) with a minimum possible amplification factor at least during a certain time interval (first portion of a time interval of the detected free fall situation); according to the first design variant or embodiment of the present invention, a phase inversion device 33 integrated in the control loop is in particular not present.

According to a second design variant or embodiment of the present invention, such a phase inversion device 33 is present as part of the control loop or drive controller 3; this is indicated in FIG. 1 by dashed representation of the phase inversion device 33.

According to the second embodiment, it is provided that, likewise for faster or more effective reduction of the (amplitude of the) drive oscillation of the mass oscillator (excited by the drive controller 3), the phase inversion device 33 generates the drive control signal 32 as a phase-inverted drive control signal at least during a certain time interval (first portion of a time interval of the detected free fall situation).

According to both embodiments, it is advantageously possible according to the present invention to achieve a reduction of the amplitude of the drive oscillation as quickly as possible, in any case significantly faster than it could be achieved by a mere dying-away process of the drive oscillation of the mass oscillator.

This is shown schematically in FIG. 2, which shows an exemplary time curve of the drive amplitude 101 with active interruption or reduction of the amplitude of the drive oscillation during a time interval 100 of the detected free fall situation: In the time before the beginning of the time interval 100, the drive amplitude 101 is shown constant, corresponding to a specified target amplitude (as the setpoint value). During a first portion 110 of the time interval 100 of the detected free fall situation, the drive amplitude 101 drops sharply (more sharply than according to a natural dying-away process). This is, for example, achieved by operating the amplifier device 31 in an operating mode with a minimum possible amplification factor (so that a significantly lower amplitude setpoint value results, which can be achieved in a very short time due to the feedback), or by applying a phase difference of 180° to the drive control signal 32 (for bringing about the driving of the mass oscillator) by means of the phase inversion device 33. A second portion 120 of the time interval 100 of the detected free fall situation begins, as shown in FIG. 2, in particular after the first portion 110 has ended, in particular either immediately following the first portion 110 or temporally spaced apart from the first portion 110. In the second portion 120 of the time interval 100 of the detected free fall situation, the drive device and/or the drive control signal 32 is in particular switched off so that a natural dying-away process takes place, in any case at the beginning of the second portion 120 of the time interval 100 and starting from a significantly reduced amplitude of the drive oscillation.

According to the first embodiment, the amplifier device 31 is operated with a minimum possible amplification factor during the first portion 110 of the time interval 100 of the detected free fall situation, i.e., the amplitude setpoint value is reduced to the lowest possible value by means of the amplification by the amplifier device 31. The expected time to reach this drive amplitude is in the order of magnitude of a few milliseconds (^{˜}O(10⁰) ms), i.e., significantly faster than natural decaying (of the amplitude) of the drive oscillation due to the attenuation in the core of the micromechanical structure 2 (MEMS core). For example, after 5 ms (during the first portion 110 of the time interval 100), the drive is switched off (second portion 120 of the time interval 100) in order to allow the remaining drive amplitude to decay naturally. If it again applies that Acc_{mag}>Accₜₕᵣₑₛₕ, the free fall situation is no longer present (i.e., the end of the free fall has been reached): The amplification by the amplifier device 31 is reset to the trim value and the drive electrodes are switched on again.

According to the second embodiment, the phase inversion device 33 of the feedback loop of the actuation control loop is present: The phase inversion device 33 in the feedback loop inverts the phase of the drive oscillation or of the drive control signal 32 (by means of a phase difference of 180°), whereby the drive amplitude is reduced significantly faster in comparison to the natural decaying during the first portion 110 of the time interval 100. This phase change can, for example, be achieved or indicated by including an inversion bit in a tab, whereby the phase inversion device 33 is configured such that such a phase change is performed depending on the inversion bit. After a certain wait time t_{wait} in the order of magnitude of a few milliseconds (^{˜}O(10⁰) ms), i.e., the first portion 110 of the time interval 100 (in particular depending on the ASIC FE), the drive electrodes are switched off in order to ensure that they do not continue to increase the drive amplitude (oscillation amplitude) (with changed phase position). If it again applies that Acc_{mag}>Accₜₕᵣₑₛₕ, the free fall situation is no longer present (i.e., the end of the free fall has been reached), the phase inversion device 33 returns to 0° from the 180° phase shift and the drive electrodes are switched on.

What is claimed is:

1. A rotation rate sensor, comprising:
a micromechanical structure and a mass oscillator, wherein the mass oscillator is drivable to a drive oscillation by a drive device, wherein the rotation rate sensor is configured to protect the micromechanical structure and, during a time interval of a detected free fall situation, in such a way that a reduction of an amplitude of the drive oscillation is achieved, wherein the free fall situation is signaled using a free fall signal supplied to the rotation rate sensor, wherein the rotation rate sensor is configured in such a way that, after reception of a further free fall signal signaling an end of the free fall situation, the drive device again drives the mass oscillator to its operative drive oscillation;
wherein the reduction of the amplitude of the drive oscillation is realized faster than in a dying-away process of the drive oscillation of the mass oscillator.

2. The rotation rate sensor according to claim 1, wherein the rotation rate sensor is configured in such a way that:
for bringing about the drive oscillation of the mass oscillator, the drive device is controlled by a drive controller including an amplifier device,
the drive controller generates a drive control signal for bringing about the driving of the mass oscillator, and
during a first portion of the time interval of the detected free fall situation, the amplifier device is operated in an operating mode with a minimum possible amplification factor;
wherein the amplifier device is an operational amplifier.

3. The rotation rate sensor according to claim 2, wherein the rotation rate sensor is configured in such a way that:
for bringing about the drive oscillation of the mass oscillator, the drive device is controlled by the drive controller which includes a phase inversion device,
the drive controller generates a drive control signal for bringing about the driving of the mass oscillator, and
during the first portion of the time interval of the detected free fall situation, the phase inversion device generates the drive control signal as a phase-inverted drive control signal.

4. The rotation rate sensor according to claim 2, wherein the rotation rate sensor is configured in such a way that, in a second portion of the time interval of the detected free fall situation, the drive device and/or the drive control signal is switched off, wherein the second portion of the time interval of the detected free fall situation begins immediately following the first portion, or begins, temporally spaced apart from the first portion, after a specified wait time.

5. The rotation rate sensor according to claim 1, wherein the rotation rate sensor is configured in such a way that the free fall situation is detected when a measured acceleration acting on the rotation rate sensor is detected as being less than an acceleration threshold value.

6. The rotation rate sensor according to claim 5, wherein the rotation rate sensor includes an acceleration sensor or is connected to an acceleration sensor, wherein the acceleration sensor is configured in such a way that the free fall situation is detected and the free fall signal is generated when a measured acceleration acting on the rotation rate sensor is detected as being less than the acceleration threshold value.

7. A method for operating a rotation rate sensor with a micromechanical structure and a mass oscillator, wherein the mass oscillator is drivable to a drive oscillation using a drive device, wherein the rotation rate sensor is configured to protect the micromechanical structure and, during a time interval of a detected free fall situation, in such a way that a reduction of an amplitude of the drive oscillation is achieved, wherein the free fall situation is signaled using a free fall signal supplied to the rotation rate sensor, wherein the rotation rate sensor is configured in such a way that, after reception of a further free fall signal signaling the end of the free fall situation, the drive device again drives the mass oscillator to its operative drive oscillation, wherein the reduction of the amplitude of the drive oscillation is realized faster than in a dying-away process of the drive oscillation of the mass oscillator, the method comprising the following steps:
driving the mass oscillator to the drive oscillation;
receiving the free fall signal;
after receiving the free fall signal, reducing the amplitude of the drive oscillation;
receiving the further free fall signal; and
after receiving the further free fall signal, driving the mass oscillator to the operative drive oscillation.
